(19) United States
(12) Patent Application Publication
(10) Pub. No.: US 2024/0242002 A1
(43) Pub. Date: Jul. 18, 2024

(54) Rotary Wing Design for Wake Vortex Mitigation

(71) Applicant: The Board of Trustees of the University of Illinois, Urbana, IL (US)

(72) Inventor: Phillip John Ansell, Urbana, IL (US)

(21) Appl. No.: 18/370,028

(22) Filed: Sep. 19, 2023

Related U.S. Application Data
(60) Provisional application No. 63/408,767, filed on Sep. 21, 2022.

(51) Int. Cl. G06F 30/15

(52) U.S. Cl. CPC G06F 30/15

(57) ABSTRACT

An example embodiment may involve determining, for a rotorcraft, input parameters including a disk diameter, a rotary velocity, a thrust coefficient, and a plurality of chord lengths across sections of a rotary wing of the rotorcraft; iteratively repeating until a convergence criterion is met: (i) determining an inflow to the rotary wing, (ii) based on the input parameters, defining a system of relationships based on vortex circulation strengths across the sections of the rotary wing, and (iii) solving the system of relationships to determine a distribution of lift across the sections of the rotary wing; and based on the distribution of lift and the plurality of chord lengths, determining local pitch angles for each of the sections of the rotary wing.

### CROSS-REFERENCE TO RELATED APPLICATION

This application claims priority to U.S. provisional patent application No. 63/408,767, filed Sep. 21, 2022, which is hereby incorporated by reference in its entirety.

### BACKGROUND

Aircraft wings are typically shaped to provide lift while also accounting for stability, control, and structural integrity. Some of the aspects of wing design that can impact lift include materials used to construct the wing, airfoil shape, surface area, angle of attack, and chord length from leading edge to trailing edge. But the production of lift by a wing often creates concentrated regions of high-velocity rotational flow in the form of vortices (e.g., tip vortices). These tip vortices result from air pressure differences between the upper and lower surfaces of the wing and can generate drag, downwash, wake turbulence, and other forms of aerodynamic interference. Not only can vortices have a negative impact on aircraft performance (e.g., in terms of reduced fuel efficiency), but they can persist in air for minutes after the aircraft has passed. This creates a hazard for other aircraft, especially during closely spaced takeoffs and landings. Furthermore, vortices can generate significant acoustic noise, which is especially undesirable for aircraft intended to be operated in residential and commercial areas.

### SUMMARY

Various implementations disclosed herein include methods for determining chord lengths and local pitch angle variations along the span of a rotary wing that are designed to mitigate wake vortex creation while taking into account constraints on the amount of lift that the rotary wing can produce. Put another way, the design allows one to trade off between rotary wing aerodynamic efficiency and reduced tip vortex strengths for a desired amount of lift. Thus, the design process is flexible, in that it can be directed to produce a rotary wing optimized for zero or near-zero vortex tip creation as well as a rotary wing optimized for minimum power to operate. This is achieved by modeling the distribution of lift along the rotary wing in a system of relationships based on vortex circulation strengths.

Accordingly, a first example embodiment may involve determining, by a computing system and for a rotorcraft, input parameters including a disk diameter, a rotary velocity, a thrust coefficient, and a plurality of chord lengths across sections of a rotary wing of the rotorcraft; iteratively repeating, by the computing system, until a convergence criterion is met: (i) determining an inflow to the rotary wing, (ii) based on the input parameters, defining a system of relationships rotary wing on vortex circulation strengths across the sections of the rotary wing, and (iii) solving the system of relationships to determine a distribution of lift across the sections of the rotary wing; and based on the distribution of lift and the plurality of chord lengths, determining, by the computing system, local pitch angles for each of the sections of the rotary wing.

A second example embodiment may involve a non-transitory computer-readable medium, having stored thereon program instructions that, upon execution by a computing system, cause the computing system to perform operations in accordance with the first example embodiment.

In a third example embodiment, a computing system may include at least one processor, as well as memory and program instructions. The program instructions may be stored in the memory, and upon execution by at least one processor, cause the computing system to perform operations in accordance with the first example embodiment.

In a fourth example embodiment, a system may include various means for carrying out each of the operations of the first example embodiment.

These, as well as other embodiments, aspects, advantages, and alternatives, will become apparent to those of ordinary skill in the art by reading the following detailed description, with reference where appropriate to the accompanying drawings. Further, this summary and other descriptions and figures provided herein are intended to illustrate embodiments by way of example only and, as such, that numerous variations are possible. For instance, structural elements and process steps can be rearranged, combined, distributed, eliminated, or otherwise changed, while remaining within the scope of the embodiments as claimed.

### BRIEF DESCRIPTION OF THE DRAWINGS

FIG. 1 illustrates a schematic drawing of a computing device, in accordance with example embodiments.

FIG. 2 illustrates a schematic drawing of a server device cluster, in accordance with example embodiments.

FIG. 3 depicts regions of a tip vortex, in accordance with example embodiments.

FIG. 4 depicts a wing with various local pitch angles and chord lengths along its span, in accordance with example embodiments.

FIG. 5 is a flow chart, in accordance with example embodiments.

FIG. 6 depicts optimal circulation distribution for a hovering rotor at C_{T}=0.01, compared to solutions of Wu and Glauert, in accordance with example embodiments.

FIG. 7 compares characteristics of a conventional wing to that of a wing designed for reduced vortex generation, in accordance with example embodiments.

FIG. 8 depicts lateral and axial views of wings with a conventional (power optimized) design and lateral and axial views of a non-conventional (wake optimized) design, in accordance with example embodiments.

FIG. 9 depicts thrust and torque related information for power optimized and wake optimized rotary wings, in accordance with example embodiments.

FIG. 10 depicts vorticity isosurfaces for power optimized and wake optimized rotary wings, in accordance with example embodiments.

FIG. 11 depicts Q-criterion isosurfaces for power optimized and wake optimized rotary wings, in accordance with example embodiments.

FIG. 12 depicts uniform and log-based weighting functions, in accordance with example embodiments.

FIGS. 13A and 13B depict solutions for vortex circulation distributions for uniform and log-based weighting, in accordance with example embodiments.

FIG. 14A depicts the impact of various balanced weightings on the predicted rotor induced torque coefficient, in accordance with example embodiments.

FIG. 14B depicts the impact of wake optimization on the predicted rotor induced torque coefficient, in accordance with example embodiments.

FIG. 15 is a flow chart, in accordance with example embodiments.

### DETAILED DESCRIPTION

Example methods, devices, and systems are described herein. It should be understood that the words “example” and “exemplary” are used herein to mean “serving as an example, instance, or illustration.” Any embodiment or feature described herein as being an “example” or “exemplary” is not necessarily to be construed as preferred or advantageous over other embodiments or features unless stated as such. Thus, other embodiments can be utilized and other changes can be made without departing from the scope of the subject matter presented herein.

Accordingly, the example embodiments described herein are not meant to be limiting. It will be readily understood that the aspects of the present disclosure, as generally described herein, and illustrated in the figures, can be arranged, substituted, combined, separated, and designed in a wide variety of different configurations. For example, the separation of features into “client” and “server” components may occur in a number of ways.

Further, unless context suggests otherwise, the features illustrated in each of the figures may be used in combination with one another. Thus, the figures should be generally viewed as component aspects of one or more overall embodiments, with the understanding that not all illustrated features are necessary for each embodiment.

Additionally, any enumeration of elements, blocks, or steps in this specification or the claims is for purposes of clarity. Thus, such enumeration should not be interpreted to require or imply that these elements, blocks, or steps adhere to a particular arrangement or are carried out in a particular order.

### I. Example Computing Devices and Cloud-Based Computing Environments

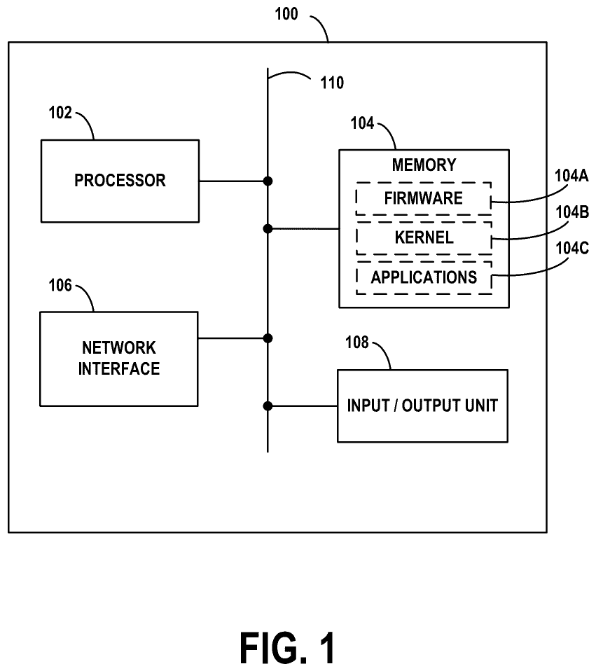

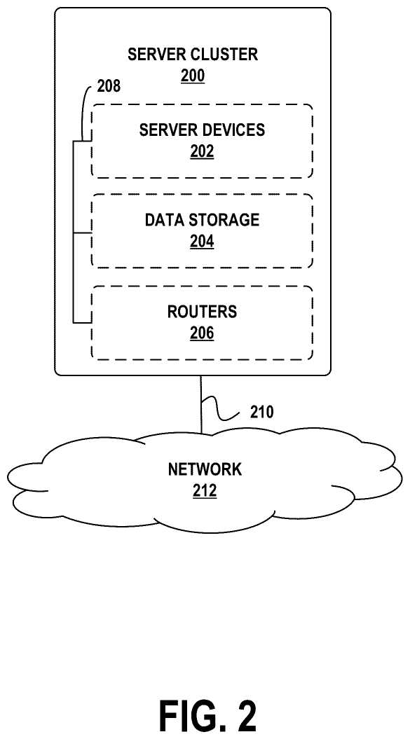

FIG. 1 is a simplified block diagram exemplifying a computing device 100, illustrating some of the components that could be included in a computing device arranged to operate in accordance with the embodiments herein. FIG. 2 is a simplified diagram of a cloud-based computing system. The computer-based embodiments of FIGS. 1 and 2 may be employed to design aircraft wings in a manner that allows vortex generation to be mitigated (e.g., through the solving of complex systems of equations, simulation, computer-aided design, and so on).

Computing device 100 could be a client device (e.g., a device actively operated by a user), a server device (e.g., a device that provides computational services to client devices), or some other type of computational platform. Some server devices may operate as client devices from time to time in order to perform particular operations, and some client devices may incorporate server features.

In this example, computing device 100 includes processor 102, memory 104, network interface 106, and input/output unit 108, all of which may be coupled by system bus 110 or a similar mechanism. In some embodiments, computing device 100 may include other components and/or peripheral devices (e.g., detachable storage, printers, and so on).

Processor 102 may be one or more of any type of computer processing element, such as a central processing unit (CPU), a co-processor (e.g., a mathematics, graphics, or encryption co-processor), a digital signal processor (DSP), a network processor, and/or a form of integrated circuit or controller that performs processor operations. In some cases, processor 102 may be one or more single-core processors. In other cases, processor 102 may be one or more multi-core processors with multiple independent processing units. Processor 102 may also include register memory for temporarily storing instructions being executed and related data, as well as cache memory for temporarily storing recently-used instructions and data.

Memory 104 may be any form of computer-usable memory, including but not limited to random access memory (RAM), read-only memory (ROM), and non-volatile memory (e.g., flash memory, hard disk drives, solid state drives, compact discs (CDs), digital video discs (DVDs), and/or tape storage). Thus, memory 104 represents both main memory units, as well as long-term storage. Other types of memory may include biological memory.

Memory 104 may store program instructions and/or data on which program instructions may operate. By way of example, memory 104 may store these program instructions on a non-transitory, computer-readable medium, such that the instructions are executable by processor 102 to carry out any of the methods, processes, or operations disclosed in this specification or the accompanying drawings.

As shown in FIG. 1, memory 104 may include firmware 104A, kernel 104B, and/or applications 104C. Firmware 104A may be program code used to boot or otherwise initiate some or all of computing device 100. Kernel 104B may be an operating system, including modules for memory management, scheduling and management of processes, input/output, and communication. Kernel 104B may also include device drivers that allow the operating system to communicate with the hardware modules (e.g., memory units, networking interfaces, ports, and buses) of computing device 100. Applications 104C may be one or more user-space software programs, such as web browsers or email clients, as well as any software libraries used by these programs. Memory 104 may also store data used by these and other programs and applications.

Network interface 106 may take the form of one or more wireline interfaces, such as Ethernet (e.g., Fast Ethernet, Gigabit Ethernet, and so on). Network interface 106 may also support communication over one or more non-Ethernet media, such as coaxial cables or power lines, or over wide-area media, such as Synchronous Optical Networking (SONET) or digital subscriber line (DSL) technologies. Network interface 106 may additionally take the form of one or more wireless interfaces, such as IEEE 802.11 (Wifi), BLUETOOTH®, global positioning system (GPS), or a wide-area wireless interface. However, other forms of physical layer interfaces and other types of standard or proprietary communication protocols may be used over network interface 106. Furthermore, network interface 106 may comprise multiple physical interfaces. For instance, some embodiments of computing device 100 may include Ethernet, BLUETOOTH®, and Wifi interfaces.

Input/output unit 108 may facilitate user and peripheral device interaction with computing device 100. Input/output unit 108 may include one or more types of input devices, such as a keyboard, a mouse, a touch screen, and so on. Similarly, input/output unit 108 may include one or more types of output devices, such as a screen, monitor, printer, and/or one or more light emitting diodes (LEDs). Additionally or alternatively, computing device 100 may communicate with other devices using a universal serial bus (USB) or high-definition multimedia interface (HDMI) port interface, for example.

In some embodiments, one or more computing devices like computing device 100 may be deployed to support distributed computing architecture. The exact physical location, connectivity, and configuration of these computing devices may be unknown and/or unimportant to client devices. Accordingly, the computing devices may be referred to as “cloud-based” devices that may be housed at various remote data center locations.

FIG. 2 depicts a cloud-based server cluster 200 in accordance with example embodiments. In FIG. 2, operations of a computing device (e.g., computing device 100) may be distributed between server devices 202, data storage 204, and routers 206, all of which may be connected by local cluster network 208. The number of server devices 202, data storages 204, and routers 206 in server cluster 200 may depend on the computing task(s) and/or applications assigned to server cluster 200.

For example, server devices 202 can be configured to perform various computing tasks of computing device 100. Thus, computing tasks can be distributed among one or more of server devices 202. To the extent that these computing tasks can be performed in parallel, such a distribution of tasks may reduce the total time to complete these tasks and return a result. For purposes of simplicity, both server cluster 200 and individual server devices 202 may be referred to as a “server device.” This nomenclature should be understood to imply that one or more distinct server devices, data storage devices, and cluster routers may be involved in server device operations.

Data storage 204 may be data storage arrays that include drive array controllers configured to manage read and write access to groups of hard disk drives and/or solid state drives. The drive array controllers, alone or in conjunction with server devices 202, may also be configured to manage backup or redundant copies of the data stored in data storage 204 to protect against drive failures or other types of failures that prevent one or more of server devices 202 from accessing units of data storage 204. Other types of memory aside from drives may be used.

Routers 206 may include networking equipment configured to provide internal and external communications for server cluster 200. For example, routers 206 may include one or more packet-switching and/or routing devices (including switches and/or gateways) configured to provide (i) network communications between server devices 202 and data storage 204 via local cluster network 208, and/or (ii) network communications between server cluster 200 and other devices via communication link 210 to network 212.

Additionally, the configuration of routers 206 can be based at least in part on the data communication requirements of server devices 202 and data storage 204, the latency and throughput of the local cluster network 208, the latency, throughput, and cost of communication link 210, and/or other factors that may contribute to the cost, speed, fault-tolerance, resiliency, efficiency, and/or other design goals of the system architecture.

As a possible example, data storage 204 may include any form of database, such as a structured query language (SQL) database. Various types of data structures may store the information in such a database, including but not limited to tables, arrays, lists, trees, and tuples. Furthermore, any databases in data storage 204 may be monolithic or distributed across multiple physical devices.

Server devices 202 may be configured to transmit data to and receive data from data storage 204. This transmission and retrieval may take the form of SQL queries or other types of database queries, and the output of such queries, respectively. Additional text, images, video, and/or audio may be included as well. Furthermore, server devices 202 may organize the received data into web page or web application representations. Such a representation may take the form of a markup language, such as HTML, the extensible Markup Language (XML), or some other standardized or proprietary format. Moreover, server devices 202 may have the capability of executing various types of computerized scripting languages, such as but not limited to Perl, Python, PHP Hypertext Preprocessor (PHP), Active Server Pages (ASP), JAVASCRIPT®, and so on. Computer program code written in these languages may facilitate the providing of web pages to client devices, as well as client device interaction with the web pages. Alternatively or additionally, JAVA® may be used to facilitate generation of web pages and/or to provide web application functionality.

### II. Wing Design for Vortex Mitigation

The formation of tip vortices in the near wake of fixed or rotary wing systems is a phenomenon associated with lift production. For a rotorcraft, these vortex systems feature a coherent collection of wake vorticity shed at the wing tips that persist and interact as the wake ages. Fundamentally, wake vortices are created due to changes in the radial lift or thrust distribution across the rotary wing radius. For a helicopter in hover, tip vortices follow a helical pattern in the vicinity below the rotor. In some examples, the tip vortices produce tight filament structures that radially compress inboard to follow the induced streamtube through the rotor. While the hover condition represents the simplest operational case of a helicopter, the wake structure is still surprisingly complex and difficult to predict.

Herein, the term “rotary wing” is used to broadly refer to various types of rotorcraft wings. Thus, the terms “rotary wing”, “rotor”, “propeller”, and “rotor blade” may be used interchangeably herein based on context.

Further, use of the terms “optimize”, “optimized”, “optimization”, “optimal”, and similar language does not imply that a best possible solution is actually achieved. Instead, these terms indicate a goal that is sought through selection of design parameters. Thus, an “optimization” procedure may produce a sub-optimal result relative to some design goal(s), while improving performance in other design goal(s), or still demonstrating an advance over previous designs.

Tip vortices can be traced to several fundamental issues in the performance of rotary wings, including vortex interactions, vortex-airframe interactions, unsteady and vibrational loading, and rotor noise. The strong concentration of vorticity and large induced velocities near the core of the rotary wing tip vortex play a dominant role in these fundamental issues of helicopter operation. Similar observations can also be stated for the interaction of axial propeller wakes used on fixed-wing aircraft.

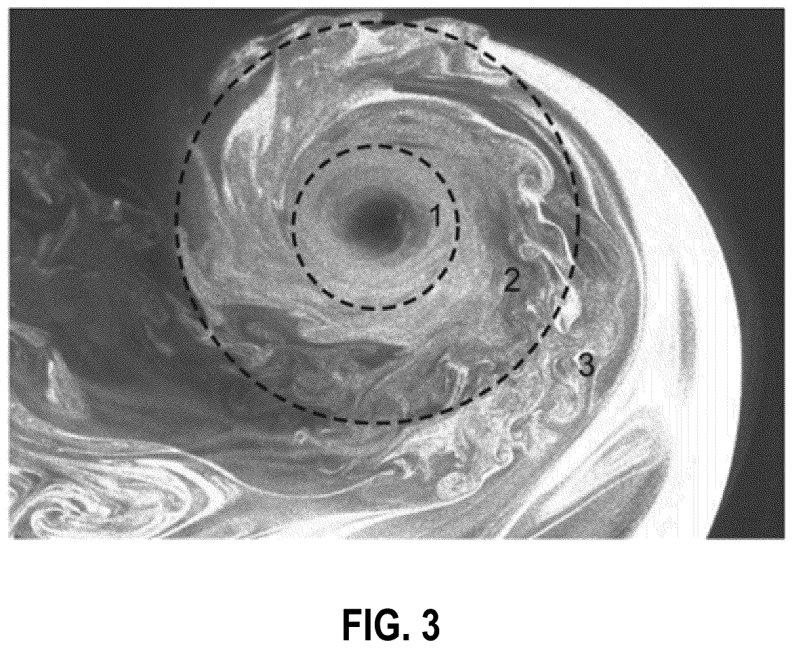

Morphologically, a rotary wing tip vortex features an innermost laminar core region, a transitional annular region, and an outside turbulent region. These three regions can be observed in FIG. 3, where labels (1), (2), and (3) correspond to the laminar, transitional, and turbulent regions of the vortex, respectively. The tip vortices produced by rotary wings are able to persist across long wake ages, as molecular diffusion becomes the only mechanism for energy dissipation across the laminar core region. Furthermore, fluid stratification effects force relaminarization of turbulent fluctuations within the region nearest to the vortex core, which exacerbates the slow dissipation effects of the vortex core.

To date, little effort has been taken to relate the physics of how a rotary wing tip vortex is formed to the configuration of rotary wing elements to mitigate or entirely eliminate tip vortices across the near-field region. Other proposed means for mitigating rotary wing tip vortex formation often include heavy and complex actuation methods, configured to break up the vortex after formation.

The classic optimum rotor loading solutions serve as a common benchmark for propeller, wind turbine, and helicopter rotor configurations. This rotary wing loading fulfills the minimum induced tip loss condition for a given thrust, and it is akin to the constant inflow condition of an actuator disk. Even with advances in modeling approaches and simulation capabilities, the optimum loading for rotary wings has continued to converge to these classic theories. However, as a consequence of using an optimal loading solution, the shed vortex circulation strength at the tip asymptotes to infinity due to the infinite radial gradient in the bound circulation at this location. This large change in circulation strength at the tip leads to the strong rotary wing tip vortex formation of a conventional rotor. Thus, in order to reduce the strength of the tip vortex and reduce the roll-up behavior of the wake vortex sheet, large localized radial gradients in bound circulation distribution should be avoided. Using this general approach, it is theoretically possible to produce a wake that avoids roll-up in the near field. In this context, the wake is said to be marginally stable since the amplification of the roll-up process is sufficiently small that it can be neglected until the far-wake region.

The embodiments herein include a design approach for removing the fundamental source of the vortex formation process, rather than seeking to eliminate the vortex after it has already formed. Therefore, it can be implemented in a passive fashion without the need for any active actuation or feedback control. Certain of these embodiments introduce an additional surface to the wing to gradually blend the lift distribution across the span of the winglet, reducing shed vortex strength by removing the fundamental source of the vortex formation process. This unique geometrical rotary wing design creates zero or near zero vortices at the wing tip allowing for noise reduction usually generated by wing-vortex interactions.

Alternatively, these techniques allow for the trading off of operational power requirements of a rotary wing versus vortex creation, so that wing characteristics can be balanced as desired or necessary. For example, it may be acceptable for certain low-flying rotorcraft to sacrifice some amount of aerodynamic efficiency to mitigate vortex creation, as doing so reduces near-ground turbulence and in-flight noise. On the other hand, these techniques also allow wing design to target negligible vortex strength by accepting potentially significant increases in power requirements. Other possibilities exist.

The discussions herein generally center on wing design for rotorcraft, such as helicopters, as well as other rotary wing devices, such as propellers and wind turbines. However, the embodiments can be more generally applied to design for fixed-wing aircraft as well. This, the focus on rotorcraft should not be viewed as limiting.

### A. Example Wing

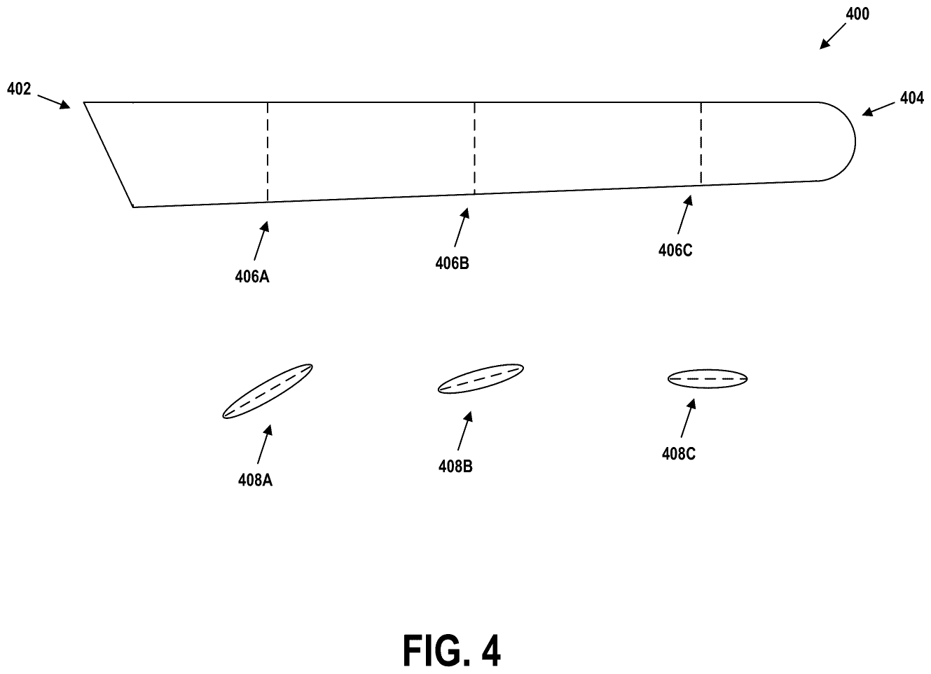

FIG. 4 depicts an example wing 400. Discussion of wing 400 introduces the terminology and design considerations that are relevant to the claimed embodiments.

The radius of wing 400 extends from root 402 (the part of the wing nearest the aircraft or nearest the rotor hub of a rotorcraft) to tip 404 (the part of the wing furthest from the aircraft or furthest from the rotor hub of a rotorcraft). Along the radius, three chords are shown, chords 406A, 406B, and 406C. Each chord is associated with a section of the radius and has a different chord length (i.e., the diameter of the wing in the instantaneous direction of its travel) and local pitch angle (not to be confused with the overall pitch of the aircraft). The respective local pitch angles 408A, 408B, and 408C for chords 406A, 406B, and 406C are shown as cross-sections of wing 400. These local pitch angles may be implemented as gradual or sudden twists in wing 400 relative to its radius. For purposes of example, local pitch angle 408A is 30 degrees, local pitch angle 408B is 15 degrees, and local pitch angle 408C is 0 degrees.

The behavior of wing 400 in terms of its lift and the characteristics of any tip vortices generated is based on a complex set of factors, including the number of sections of wing 400, their chord lengths, and their local pitch angles. As noted, the chord lengths and local pitch angles are generally selected with the intent of maximizing lift. However, they can also be selected with the intent of minimizing tip vortex strength or balancing between the two.

### B. Free Wake Analysis & Finite Vortex Rotor Lifting Line

Since vortex roll-up is predominantly based on inviscid interactions across the vortex sheet, vortex methods can be utilized. This description serves as an introduction to the theory embodied within the rotor optimization methods used. The design optimization routines utilize a rotating finite lifting line approach within the MATLAB programming environment. This method considers the influence of the wake system on the induced velocity on the lifting line. For a fixed wing, a rigid wake is assumed and the influence of the wake on the lifting line can be modeled using a series of semi-infinite vortex filaments, or infinite horseshoe vortex element loops. Conversely, for a rotating wing, the wake is also assumed to be rigid (hence, roll-up effects are neglected), but the induced velocities in the axial and tangential directions are determined based on a series of helical vortex filaments or horseshoe vortex systems. Moreover, the exact shape of this helical vortex pattern is dependent on these induced velocities, resulting in a recursive approach to effectively resolve this coupling between the wake shape and wake-induced velocities.

It should be stressed that these are low-order optimization routines and not intended to provide a high-fidelity analysis of the rotor wake dynamics or more complex interactions. The use of low order approaches enables an analytical optimum to be produced, such that the selected configuration is the global optimum within the limitations provided by the simplifying assumptions.

The design optimization routines are built on the Lagrange multiplier method, which allows the value of one or more independent variables to be determined which optimally satisfies a given cost function. For a standard rotor design, it is typically desired to minimize the power (or aerodynamic torque at a given rotational velocity) required for a given operating condition. This torque requirement is produced through the integrated product of the tangential force and the associated moment arm from the rotational axis, for each rotary wing. In an ideal sense the tangential force distribution across a rotary wing includes (i) inviscid contributions of induced axial velocities interacting with wing-bound circulation, and (ii) viscous contributions of profile drag associated with wing-element airfoils. Thus, it is desirable to determine what distribution of wing-element circulation strength produces the lowest aerodynamic torque of the integrated rotor system.

However, constraints to the optimization problem should also specify desired operating conditions of the rotor system. Implementing a thrust constraint allows the optimal circulation distribution to be more specifically identified about some desired behavior of the rotor system. Thus, the cost function, J, for the optimization problem can be specified as:

$$J = Q + λ ( T - {T}_{spec} )$$

Where Q is torque, T is thrust, and T_{spec} is the desired target thrust. The value of the Lagrange multiplier, λ, is always positive, so incorporating a constraint in this way ensures that the specified thrust is produced by the optimal circulation distribution through an equality constraint. Thrust values below that specified are mathematically inadmissible and thrust values above that specified result in a penalty (increase) in the cost function value. The optimal combination of independent variables that minimizes the cost function is determined by taking the partial derivatives with respect to all independent variables and setting them equal to zero. Mathematically, this condition ensures that the cost function is at a minimum value, and any perturbation in any independent variable from that condition results in an increase in the value of J. For this case in particular, the independent variables are the vortex circulation strengths across the rotary wing, Ti, and the value of the Lagrange multiplier. Thus:

$$\{ \begin{matrix}\frac{\partial J}{\partial {Γ}_{i}} = 0 for i = 1 , 2 , … , I \\ \frac{\partial J}{\partial λ} = 0\end{matrix} \}$$

As indicated previously, vorticity is shed into the wake of the rotary wing due to gradients in the lift generated across the radius. As a means to reduce the strength of this gradient at the wing tip, the cost function was augmented with an equality constraint on the bending moment achieved at the rotary wing hub, due to the aerodynamic lift profile. This additional constraint provides a new cost function:

$$J = Q + {λ}_{1} ( T - {T}_{spec} ) + {λ}_{2} ( B - {B}_{spec} )$$

Where B is the wing-hub bending moment and B_{spec} is the desired target bending moment. This variable was used to bias the lift generation of the rotary wing to certain regions of the span. By specifying the wing-hub bending moment to be lower than that achieved using the initial cost function, the lift profile was shifted inboard across the wing. The wing-hub bending moment that corresponded to a zero-gradient lift profile at the tip was iteratively determined, which coincided with a design corresponding to zero wake vortex strength.

Further limitations on the circulation strength admissible across any given rotary wing section can also be integrated into the cost function in the form of inequality constraints. Such an approach is desirable when limiting the lift coefficient of a given rotary wing element not to exceed the stall value. Using the vortex system strengths, the thrust, torque, and wing-hub bending moment of the rotary wing can be determined using:

$$T = ρ N {\sum }_{i = 1}^{M} [ ( Ω {r}_{i} + {U}_{{t}_{i}} + {v}_{{t}_{i}} ) {Γ}_{i} - \frac{1}{2} {V}_{i} ( {U}_{{a}_{i}} + {v}_{{a}_{i}} ) {c}_{i} {C}_{{d}_{i}} ] Δ {r}_{i}$$

$$Q = ρ N {\sum }_{i = 1}^{M} [ ( {U}_{{a}_{i}} + + {v}_{{a}_{i}} ) {Γ}_{i} + \frac{1}{2} {V}_{i} ( Ω {r}_{i} + {U}_{{t}_{i}} + {v}_{{t}_{i}} ) {c}_{i} {C}_{{d}_{i}} ] {r}_{i} Δ {r}_{i}$$

$$B = ρ N {\sum }_{i = 1}^{M} [ ( Ω {r}_{i} + {U}_{{t}_{i}} + {v}_{{t}_{i}} ) {Γ}_{i} - \frac{1}{2} {V}_{i} ( {U}_{{a}_{i}} + {v}_{{a}_{i}} ) {c}_{i} {C}_{{d}_{i}} ] {r}_{i} Δ {r}_{i}$$

Where N is the number of blades on the rotor, M is the number of vortex elements per blade, Uₐ_{ᵢ} is the rotor freestream axial velocity in feet/second at a given vortex element, Uₜ_{ᵢ} is the freestream rotary wing tangential velocity in feet/second at a given vortex element, vₐ_{ᵢ} is the induced axial velocity at in feet/second at a given vortex element, and vₜ_{ᵢ} is the induced wing-tangential velocity in feet/second at a given vortex element. Also, cᵢ is the chord length that gives rise to the ith vortex element.

These representations are then substituted into the cost function J. However, several terms in these equations are also functions of the rotary wing circulation strength distribution. Notably, the axial and tangential induced velocities (Vₐ_{ᵢ} and Vₜ_{ᵢ}, respectively), the velocity scalar (Vᵢ) as the induced velocities contribute to its value, and the profile drag coefficient (C_{d}_{ᵢ}). Here the drag, C_{d}, is assumed to vary quadratically with the airfoil lift coefficient, Cₗ, as is commonly observed in drag polars for conventional airfoils.

$${C}_{d} = {C}_{{d}_{o}} + {C}_{{d}_{1}} {C}_{l} + {C}_{{d}_{2}} {C}_{l}^{2}$$

The equations herein may employ the profile drag coefficient when it is known. When an inviscid model is assumed, the profile drag coefficient may be omitted.

The coefficients of the second order fit can be configured to also be a function of the local Reynolds number, based on the chord distribution utilized during the given iteration of the optimization. The rotary wing element lift coefficient is related to the local circulation through a combination of Kutta-Joukowski Theorem and the lift coefficient

### Definition

$${C}_{l} = \frac{2 Γ}{Vc}$$

Determining the induced velocities, however, is not as straightforward as applying the conventional Biot-Savart law as would be utilized in fixed-wing applications. Instead, the closed form solution of Wrench is utilized. This formulation allows the induced velocity contribution of a single helical vortex filament to be calculated at the control point of each bound vortex element. It is also worth noting that this solution allows the induced velocities to be more specifically defined for any number of rotary wing elements, which is one advantage over use of actuator disk methods which indirectly assume a model using an infinite number of rotary wings. Given the extensive nature of this expression, it is omitted here for brevity. However, this solution does allow the circulation strengths of the vortex elements to be factored out of the calculations, with the associated incremental velocity contributions to be determined based solely on geometric properties of the radial shedding position and the control point on the bound vortex.

$$Δ {v}_{{a}_{ij}} = Δ \overline{{v}_{{a}_{lj}}} {Γ}_{j}$$

$$Δ {v}_{{t}_{lj}} = Δ \overline{{v}_{{t}_{lj}}} {Γ}_{j}$$

$${v}_{{a}_{i}} = {\sum }_{j = 1}^{M} Δ {v}_{{a}_{ij}}$$

$${v}_{{t}_{i}} = {\sum }_{j = 1}^{M} Δ {v}_{{t}_{i j}}$$

By substituting these representations of drag coefficient and velocities into the cost function, an associated expression is obtained which is a function of only independent variables, (Γ and λ) of zero, first, or second order. It should be noted that when taking this step, it is assumed that the profile drag contribution on the thrust constraint can be neglected. Taking the partial derivative of the cost function with respect to all independent variables thus creates a system of equations that are linear functions in all Γᵢ and λ terms. Setting all partial derivatives to zero and placing the variable-dependent and constant valued terms to opposite sides of the resulting equations produces:

$$[ \begin{matrix}{b}_{1} \\ {b}_{2} \\ ⋮ \\ {b}_{m} \\ {b}_{λ}\end{matrix} ] = [ \begin{matrix}{a}_{11} & {a}_{12} & {a}_{11} & {a}_{1 M} & {a}_{1 λ} \\ {a}_{22} & {a}_{22} & {a}_{22} & {a}_{1 M} & {a}_{2 λ} \\ ⋮ & & ⋱ & & \\ {a}_{M 1} & {a}_{M 2} & {a}_{M 1} & {a}_{MM} & {a}_{M λ} \\ {a}_{λ1} & {a}_{λ2} & {a}_{λ1} & {a}_{λ M} & {a}_{λλ}\end{matrix} ] [ \begin{matrix}{Γ}_{1} \\ {Γ}_{2} \\ ⋮ \\ {Γ}_{M} \\ λ\end{matrix} ]$$

### Or:

$$b = A Γ$$

This linear system set of equations represents a distribution of lift from root to tip of a rotary wing with chord lengths cᵢ.

The optimal circulation distribution can simply be determined by solving the equations. However as stated earlier, the vortex induced velocities are dependent on the geometry of the helical vortex wake and their relative position to the bound vortex control point. Since the specific shape and axial spacing of the helical wake is a function of the axial flow velocity, the circulation strengths directly impact the geometry used in calculating the induced velocities themselves. This interdependency is resolved through an iterative scheme.

The optimization routine is configured such that an initial solution for the induced inflow across the rotor disk is assumed, here based on actuator disk theory, and the geometry of the helical wake is determined. From there, the optimal circulation distributions are determined using the solution process to the linear system of equations shown above, and these new circulation distributions are used to obtain new induced velocity profiles across the rotary wing. These new induced velocities are used to define a new wake shape, a new linear system of equations is generated, and a new optimal circulation distribution is determined. This process repeats until the circulation distribution does not change significantly with further iteration (e.g., it stays within a prescribed tolerance), signifying convergence.

With the circulation distributions and induced velocities known, the local geometric conditions produced across the rotary wing sections can be determined. The circulation is used, with a known chord and effective velocity scalar produced across that rotary wing section, to determine the sectional lift coefficient. This lift coefficient is used alongside the zero-lift angle of attack and lift-curve slope to determine the angle of attack required for that rotary wing section. By adding this angle of attack to the velocity pitch angle, produced by a combination of the wake-induced and rotor freestream velocities, the local pitch angle of the rotary wing section is determined.

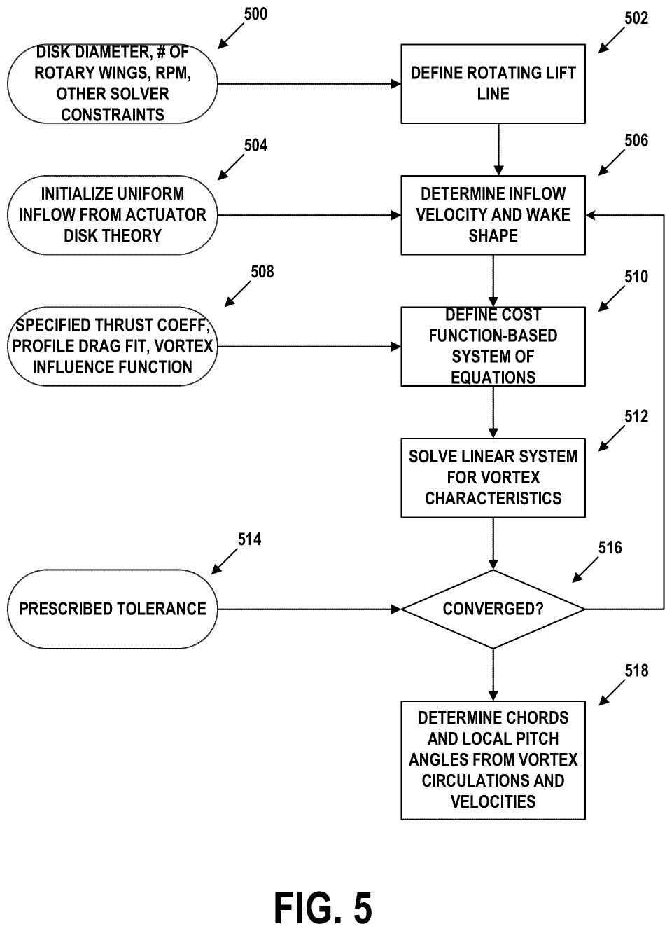

A representation of the algorithmic process used by the code is shown in FIG. 5 as a flow chart of blocks. In this figure, input data are generally represented as ovals, processing steps are generally represented as rectangles, and decisions are generally represented as diamonds.

At block 500, disk diameter (the diameter of a rotary wing, which can vary with load due to coning), the number of rotary wings of the rotorcraft, the inflight RPM of the rotary wings, and possibly other solver constraints are provided to the algorithm. At block 502, a rotating line lift is defined, containing information about how the rotary wing radius is segmented into panels of chord cᵢ and radial span Δᵣ_{ᵢ}.

At block 504, uniform inflow is initialized based on actuator disk theory. Here, the rotor is represented as a permeable disk that allows passage of the flow. The inflow is provided to the algorithm. At block 506, inflow velocity distribution (Vₐ_{ᵢ}+Uₐ_{ᵢ}) is determined, alongside the corresponding wake shape due to advection of the velocity field.

At block 508, a specified thrust coefficient (C_{T}_{_{spec}}), a profile drag coefficient (C_{d}_{ᵢ}), and a vortex influence function (aᵢ_{ⱼ}) are provided to the algorithm.

At block 510, the system of equations (b=AΓ) is determined based on the cost function (J). At block 512, this system of equations is solved for vortex characteristics (e.g., circulations and velocities). This may take the form of a distribution of lift from the root to the tip of a rotary wing.

At block 514 a prescribed tolerance for convergence of the solver is provided. At block 516, this tolerance is used to determine whether the solver has converged (e.g., changes to the circulation distribution are within the tolerance).

At block 518, and from the vortex circulations and velocities, chord lengths and local pitch angles of the rotor that can achieve the determined distribution of lift are determined.

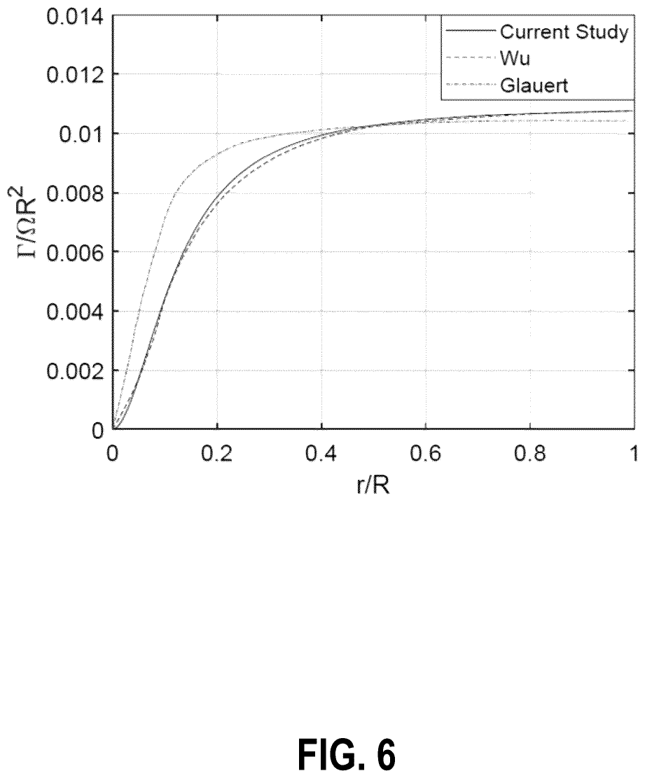

In order to demonstrate the validity of this approach, these rotor design routines were validated against classic solutions produced by Wu and Glauert assuming a rotor in hover (Uₐ=Uₜ=0). Both references assume an actuator disk, so the number of rotary wings was simply given a large value of N=999. The optimal circulation distributions corresponding to a thrust coefficient of C_{T}=0.01 are shown in FIG. 6. The results produced by Wu are expected to provide a more physical representation of an actual rotor, as it includes impacts of wake rotation, wake constriction, and other effects not included in Glauert's initial theories.

To perform chord optimization, a second iteration loop is used to perturb chord distributions, assuming a fixed circulation distribution. Since the cost function includes terms of second order in Cₗ, Newton's method (an iterative numerical technique for finding approximate solutions to real-valued equations by repeatedly refining an initial guess using the function and its derivative until a sufficiently accurate solution is obtained) can be used to iteratively assess the combinations of cᵢ and Cₗ_{ᵢ}, that results in the minimum cost function value. Following this convergence process, further perturbations are made to the chord profiles until convergence of this outer-loop condition, where further variation in the chord lengths do not result in any appreciable reductions in rotor torque.

Once the distribution of Cₗ is known, either by using a prescribed or optimized chord distribution, the angle of attack for that rotary wing section is determined based on the lift coefficient. The local pitch angle of the rotary wing section is determined based on the desired angle of attack and the angle of the velocity vector local to the given spanwise position.

III. Comparison with Conventional Wing

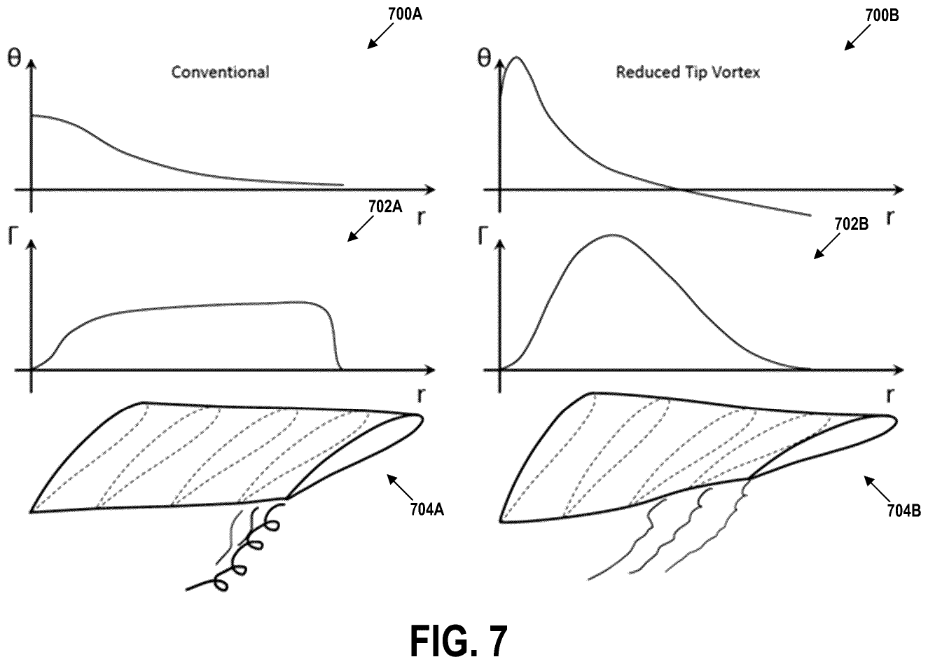

An illustration of the characteristics of a conventional wing and that of a wing designed for reduced tip vortex generation is shown in FIG. 7. The left side of FIG. 7 shows characteristics of a conventional wing and the right side of FIG. 7 shows characteristics of a non-conventional wing designed for reduced tip vortex generation.

Representation 700A shows the pitch angle of the rotary wing, θ, along its radius, r. Representation 702A shows corresponding vortex circulation strengths, Γ, along this radius. Representation 704A shows a sketch of the conventional wing's shape and the generated vortices. Representation 700B shows the pitch angle of the non-conventional rotary wing, θ, along its radius, r. Representation 702B shows corresponding vortex circulation strengths, Γ, along this radius. Representation 704B shows a sketch of the non-conventional wing's shape and the generated vortices.

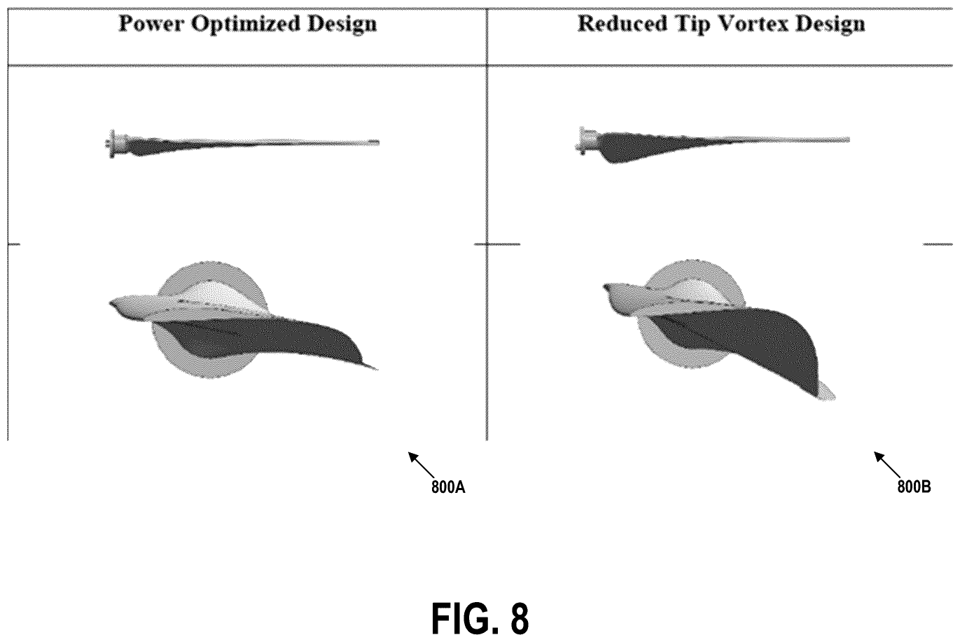

Of note is that the vortex circulation strengths are greatly reduced at the tip of the non-conventional wing, approaching or reaching zero. This establishes that, in principle, wing design can be optimized to reduce or eliminate tip vortex generation in at least some situations. FIG. 8 depicts further engineering illustrations of example wings, including lateral and axial views 800A of a conventional (power optimized) design and lateral and axial views 800B of a non-conventional (reduced tip vortex) design for the same thrust generation.

Conventional power-optimized radial loadings for rotary wings typically exhibit a relatively uniform wing bound circulation across the span that leads to a steep drop in circulation across the tip. As a result, it can be expected from Helmholtz's theorems that this sudden change in loading at the tip of a conventional rotary wing will serve as a significant source of shed vorticity into the wake. Another implication is that altering the distribution of bound circulation to vary gradually in the radial direction at the tip could have an associated impact of attenuating tip vortex roll-up characteristics. It should be noted, however, that leveraging this property for tip vortex reduction will result in a wing load profile of lower efficiency, or figure of merit, than a conventionally power-optimized wing. Therefore, the tradeoff between efficiency and acoustic properties can be taken into account in applications of this approach.

Two sets of rotary wings were designed using wing loadings obtained from the outlined optimization routines. The thrust and bending moment constraints were prescribed using the following definitions of thrust (C_{T}) and bending moment (C_{B}) coefficients, assuming an inviscid flow:

$${C}_{T} = N \frac{{\sum }_{i = 1}^{M} ( Ω {r}_{i} + {U}_{{t}_{i}} + {v}_{{t}_{i}} ) {Γ}_{i} Δ {r}_{i}}{π {R}^{4} {ω}^{2}}$$

$${C}_{B} = N \frac{{\sum }_{i = 1}^{M} ( Ω {r}_{i} + {U}_{{t}_{i}} + {v}_{{t}_{i}} ) {Γ}_{i} {r}_{{c}_{i}} Δ {r}_{i}}{π {R}^{5} {ω}^{2}}$$

In the baseline two-wing rotor design, also referred to as the power-optimized design, the only constraint applied was C_{T}_{_{SPEC}}=0.003, resulting in a lightly loaded rotor configuration. In the reduced tip vortex roll-up wing design, also referred to as the wake-optimized design, constraints of C_{T}_{_{SPEC}}=0.003 and C_{B}_{_{SPEC}}=0.00148 were applied.

Changing the radial loading from the power-optimized design results in a tradeoff in performance. This can be seen in the predicted induced torque (C_{Q}) for each rotary wing, which was 0.0001216 for the power-optimized and 0.0001692 for the wake-optimized rotary wing, which corresponds to a 30.9% increase in predicted induced torque. This difference appears to indicate a fundamental tradeoff between performance and wake characteristics; however, it should be noted that the model is assumed inviscid, and therefore does not take into account other potentially significant contributions to overall rotor torque. Despite this predicted penalty, it will be shown below that there was minimal difference between the measured torques of each design. Additionally, the wake-optimized case was selected as the canonical limit in asymptotic behavior of wake roll-up mitigation, suggesting the existence of a more balanced design space appropriate for specific applications.

Thrust and torque data were collected across a sweep of RPM in order to characterize and compare the performance of each rotary wing design. Thrust and torque coefficients (C_{T},C_{Q}) were calculated using ambient conditions and the definitions shown in the equations above. These parameters were then used to calculate figure of merit, FM, according to:

$$FM = \frac{ideal hover power}{a ctual hover power} = \frac{{C}_{T}^{3 / 2}}{{C}_{P} \sqrt{2}}$$

Where Cₚ is the coefficient of power defined as:

$${C}_{P} = \frac{P}{ρ π {R}^{5} {ω}^{3}}$$

### And:

$$P = ω Q$$

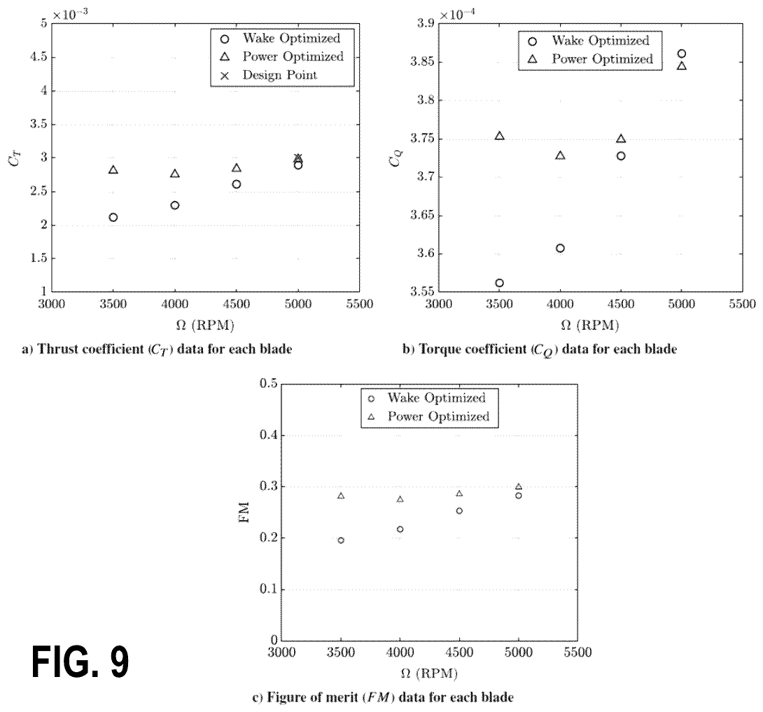

It should be noted that the model used to design the rotary wings is inviscid, so there was an expected difference between the predicted and measured C_{Q} values. Measured C_{T}, C_{Q}, and FM values for each design are shown in FIG. 9.

The FM value for both rotary wing designs was approximately 0.3 at the design operating condition, which was found to be comparable to that of similar low-Reynolds-number rotary wing platforms at similar rotary wing loading coefficients. These relatively low FM values can be attributed to the low Reynolds number and disk loading. In this regime, the effects of viscous profile drag can be significant compared to the low operating thrust, resulting in a lower figure of merit compared to rotors operating at higher Reynolds numbers and operating thrust.

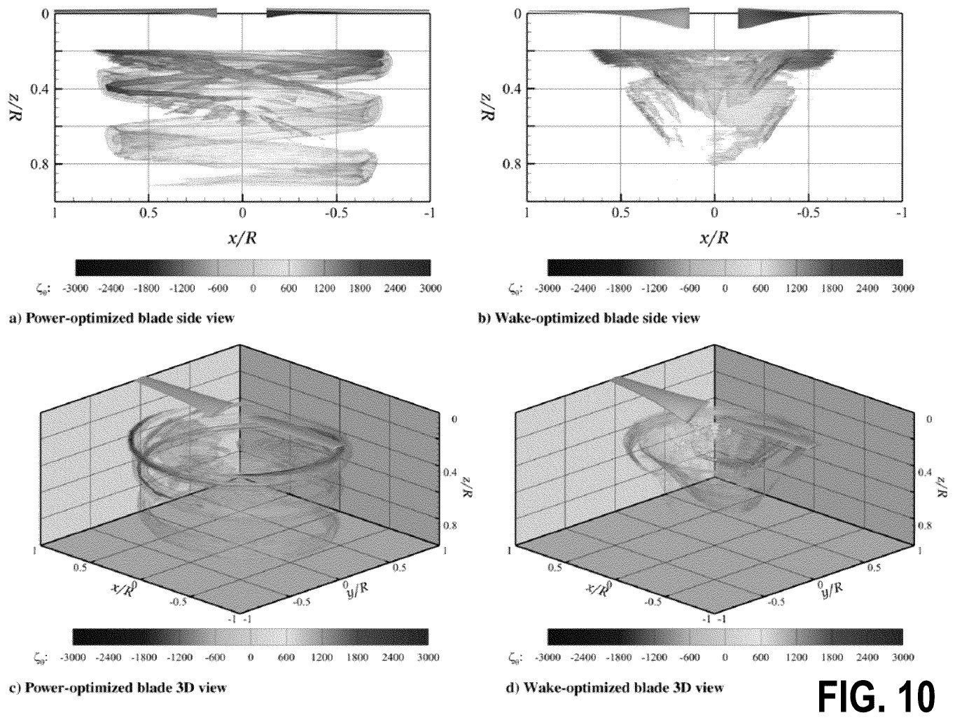

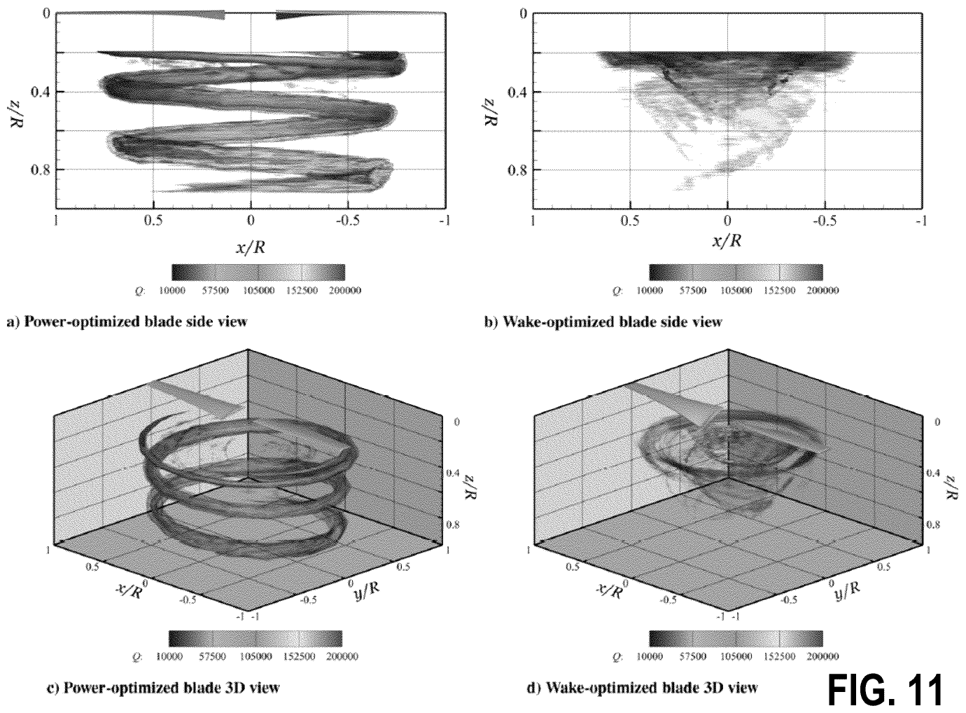

To further characterize the wake structures of each rotary wing design, the out-of-plane vorticity ζ_{θ} and Q-criterion data from all collected phase angles were linearly interpolated in a cylindrical mesh to produce 3D isosurfaces for each parameter. Plots of ζ_{θ} and Q-criterion for each rotary wing are shown in FIGS. 10 and 11, respectively. Renderings of the rotary wings at their relative positions in space are included in each of the plots for reference.

For each rotary wing configuration in FIG. 10, isosurfaces were drawn for ζ_{θ}=−200, 300, 600, 1200, 2200, and 3000s⁻¹. The wake of the power-optimized rotary wing shown in part (a) of FIG. 10 features a distinct helical structure that gradually contracts radially with further propagation in the axial direction. In addition, the shear layers shed by each wing can be seen as the helical sheets of opposing vorticity that persist until approximately z/R=0.65. The two compact regions ζ_{θ}=3000s⁻¹ near the rotor disk correspond to the tip vortices shed by each rotary wing, although they can be seen to merge into one helical structure by z/R=0.3. The wake-optimized rotary wing shown in part (b) of FIG. 10 features a significantly different wake structure that is characterized by conical sheets of vorticity, with dramatically reduced peak vorticity. In addition, the isosurface of ζ_{θ}=300 can be seen to only persist until z/R=0.68, whereas the helical wake from the power-optimized rotary wing of equal ζ_{θ} can be seen to persist to the data boundary at z/R=0.9, which suggests that it may even continue further in the axial direction.

Another notable feature of the conical vortex sheet of the wake-optimized rotary wing is its faster radial contraction in the axial direction compared to the helical structure of the power-optimized rotary wing. This could be a favorable characteristic from a wing-vortex interaction perspective given the lower speeds of the inboard rotary wing sections that might interact with the vortex sheet.

An examination of the Q-criterion data for each rotary wing yields similar conclusions to the planar data and 3D vorticity isosurface data. The power-optimized rotary wings in part (a) of FIG. 11 shed distinct helical tip vortices that merge by z/R=0.3. The absence of helical sheet structures in the power-optimized Q-criterion wake suggests that the sheets of opposing vorticity seen in parts (a) and (c) of FIG. 10 correspond to the shear layer shed by the rotary wing. In contrast, no coherent tip vortex structure is present in the Q-criterion data for the wake-optimized rotary wing in part (b) of FIG. 11. Instead, conical sheets of small Q-criterion values can be seen to correspond to the sheets of vorticity part (b) of FIG. 10. In addition, the isosurface at Q=50000 can be seen to persist within r/R<0.45 in fragments that continue to contract toward the center at z/R=0.45. The isosurface for the power-optimized rotary wing at the same Q value, on the other hand, maintains a distinct helical structure at approximately r/R=0.65 with minimal contraction until z/R=0.85.

### IV. Modified Wing Design for Balancing of Power and Wake Mitigation

The embodiments described in this section follow those above but achieve a customizable tradeoff between power and wake mitigation. This section uses notation that is similar, but might not exactly match, the notation used above.

The alternative approach replaces the bending moment equality constraint with a penalty term related to the gradient of circulation in the radial direction at each rotary wing radial location. The alternative approach applies a modified cost function, J:

$$J = {a}_{1} Q ( {Γ}_{i} ) + {λ}_{T} ( T ( {Γ}_{i} ) - {T}_{spec} ) + {a}_{2} S ( {Γ}_{i} )$$

Where:

$$S = {\sum }_{i = 1}^{N - 1} w ( {\hat{r}}_{i} ) {( \frac{d {Γ}_{i}}{d {\hat{r}}_{i}} )}^{2}$$

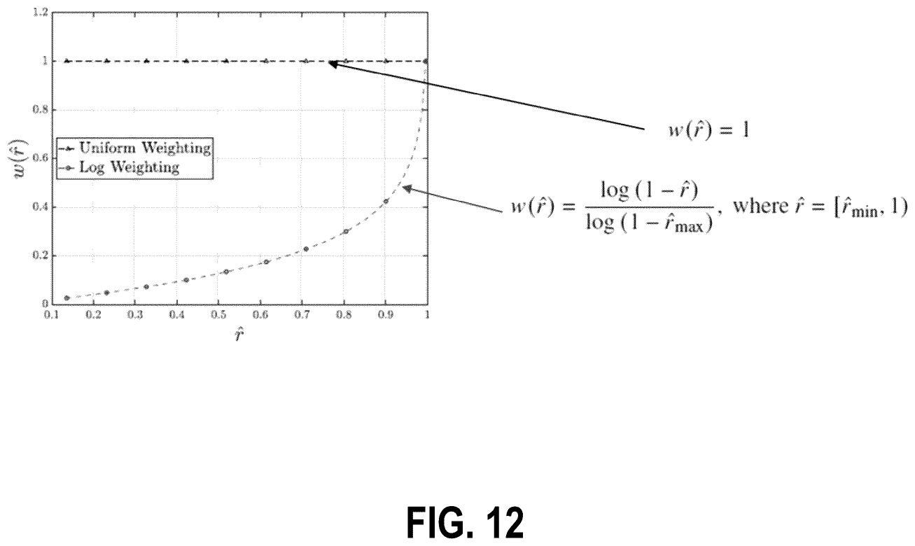

The approach introduced previously offers a methodology for tuning between the power optimized result, and a modified wake result with low circulation approaching the rotary wing tip, and near zero circulation derivative at the tip. Here, the weighting function w(\hat{r}) controls the penalty to wake vorticity applied along the span. Examples of uniform and log-based weighting functions are shown in FIG. 12.

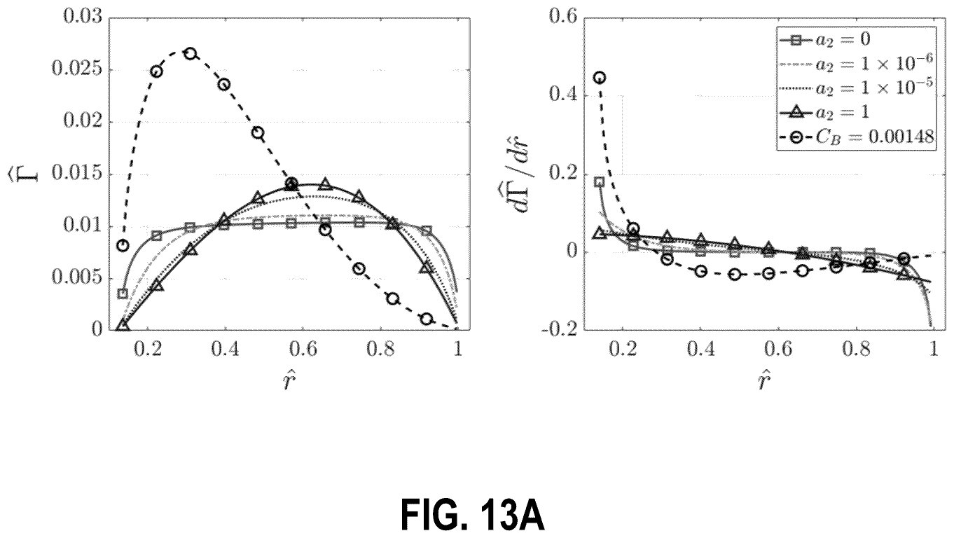

The ratio of α₂/α₁ can then be used to effectively tune the influence of the power optimization and wake vortex strength optimization terms. Examples of the multi-objective optimized solutions for circulation distributions obtained from the expression for J are shown in FIG. 13A for the uniform weighting function and in FIG. 13B for the log weighting function, where α₁=1, and α₂ was varied from 0 to 1, with α₂=0 corresponding to the power optimized case. In FIGS. 13A and 13B, the dashed curves with open-circle markers correspond to the wake optimized result developed in using the cost function from the previous section.

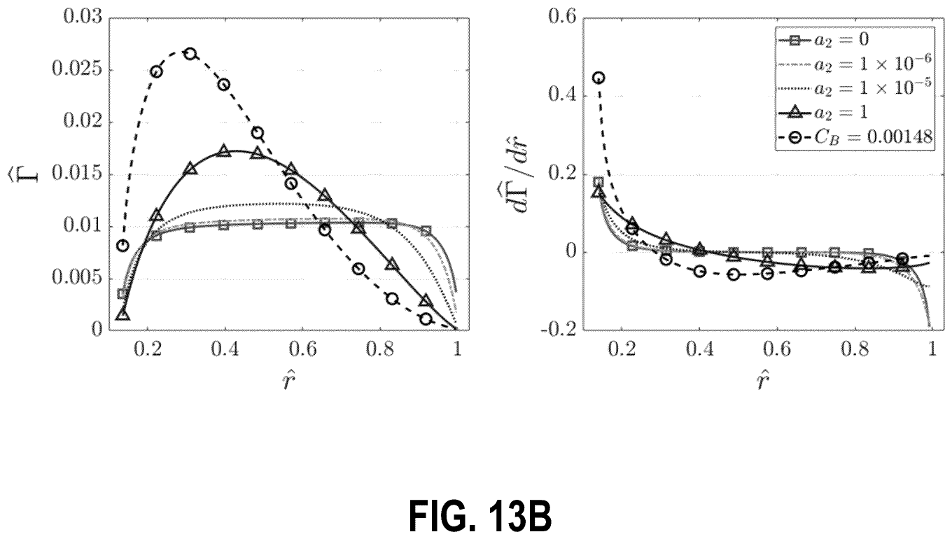

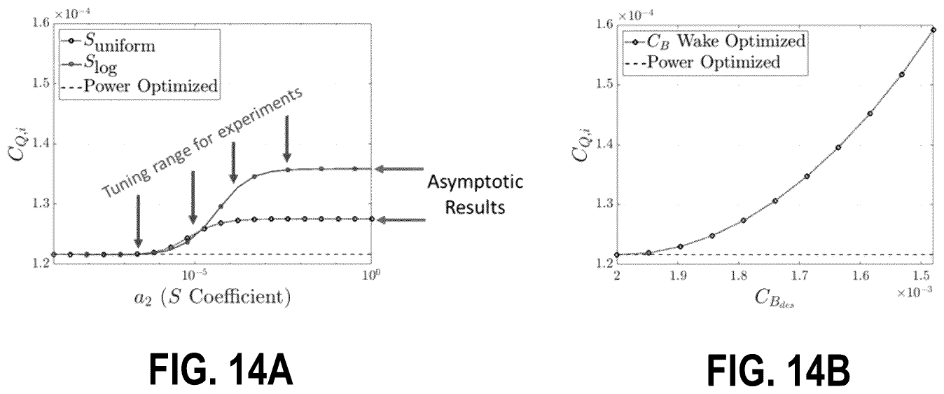

The predicted rotor induced torque coefficient (C_{Q}) was calculated for span load designs using both the S_{uniform} and S_{log} terms in the cost function for α₂ values ranging from 0 to 1. Here, C_{Q} provides an indication of the power required to operate the rotary wing system. These values of C_{Q} are plotted versus α₂ in FIG. 14A. It can be seen that both formulations result in increased C_{Q} compared to the power optimized case. However, this increasing trend is much smaller than the trend of C_{Q} for the wake optimized approach using the wing-hub bending moment, which is shown FIG. 14B. It can be seen that the S_{log} approach is able to produce a span load distribution with

$$\frac{d \hat{Γ}}{d \hat{r}}$$

values of comparable magnitude to the bending moment optimized case in the outboard region but with a 15% lower value of C_{Q}. In addition, the maximum circulation strengths of the span load distributions from the S_{log} approach are lower than those from the bending moment optimized approach, which would correspond to less aggressive twist distributions that may have more robust performance at varied inflow conditions.

### V. Example Technical Improvements

These embodiments provide a technical solution to a technical problem. One technical problem being solved is mitigation of wake vortex generation in rotary wings. In practice, this is problematic because these vortices produce lingering turbulence that can impact the flight stability of other aircraft in the vicinity, as well as acoustic noise.

In the prior art, rotary wings were designed to maximize lift and minimize power required for operation. However, these techniques can result in the rotary wings generating significantly strong vortices along their spans. While using different chord lengths and local pitch angles for different sections along the span of a rotary wing can impact wake field generation in some situations, there was no efficient and comprehensive methodology for designing such rotary wings for vortex mitigation or both operating power and vortex mitigation. Other proposed techniques require heavy and complex actuation methods, configured to break up the vortex after formation. Even other proposed techniques require the installation of secondary surfaces that add weight and balance challenges to wing operation, and in so doing, change wing lift characteristics from those originally intended. Thus, prior art techniques did little if anything to address the problems.

The embodiments herein overcome these limitations by providing techniques for trading off the power required and vortex wake characteristics of a rotary wing in the design phase. This results in several advantages. First, vortex generation can be reduced, in some cases to zero or near zero at the wing tip, given a desired amount of lift or thrust required. Second, given a distribution of lift characteristics across a rotary wing, multiple arrangements of sectional chord lengths and local pitch angles may be found to achieve vortex mitigation. Third, the vortex mitigation also reduces the acoustic footprint of the aircraft, making it operation quieter. The premises herein have been verified both analytically and through experiments under realistic in-flight parameters.

Other technical improvements may also flow from these embodiments, and other technical problems may be solved. Thus, this statement of technical improvements is not limiting and instead constitutes examples of advantages that can be realized from the embodiments.

### VI. Example Operations

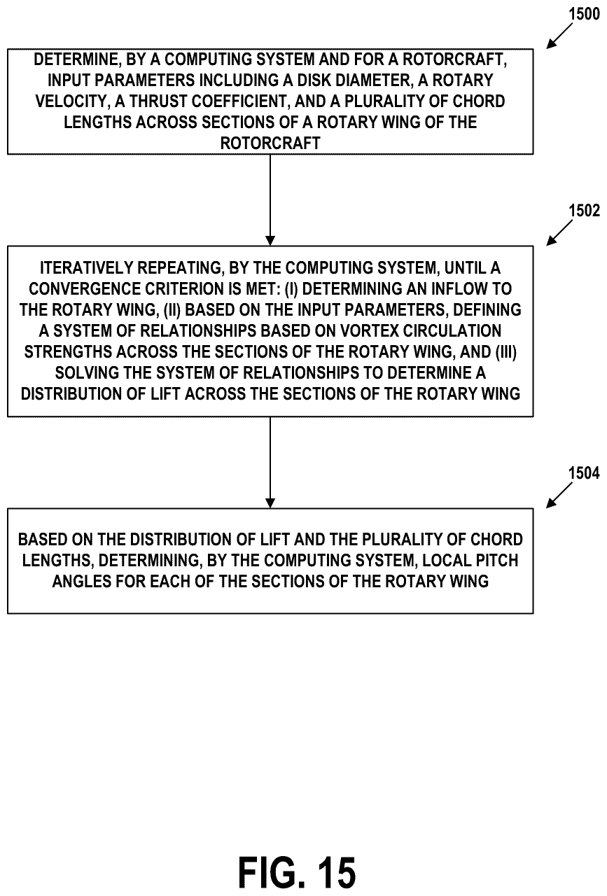

FIG. 15 is a flow chart illustrating an example embodiment. The process illustrated by FIG. 15 may be carried out by a computing device, such as computing device 100, and/or a cluster of computing devices, such as server cluster 200. However, the process can be carried out by other types of devices or device subsystems. For example, the process could be carried out by a portable computer, such as a laptop or a tablet device.

The embodiments of FIG. 15 may be simplified by the removal of any one or more of the features shown therein. Further, these embodiments may be combined with features, aspects, and/or implementations of any of the previous figures or otherwise described herein.

Block 1500 may involve determining, by a computing system and for a rotorcraft, input parameters including a disk diameter, a rotary velocity, a thrust coefficient, and a plurality of chord lengths across sections of a rotary wing of the rotorcraft.

Block 1502 may involve iteratively repeating, by the computing system, until a convergence criterion is met: (i) determining an inflow to the rotary wing, (ii) based on the input parameters, defining a system of relationships based on vortex circulation strengths across the sections of the rotary wing, and (iii) solving the system of relationships to determine a distribution of lift across the sections of the rotary wing.

Block 1504 may involve, based on the distribution of lift and the plurality of chord lengths, determining, by the computing system, local pitch angles for each of the sections of the rotary wing.

Some examples may include manufacturing the rotary wing based on the chord lengths and local pitches for each of the sections of the rotary wing.

In some examples, the convergence criterion comprises the vortex circulation strengths remaining within a tolerance value between iterations.

In some examples, solving the system of relationships to determine the distribution of lift across the sections of the rotary wing comprises using a Lagrange method with a cost function that is based on torque produced by the rotary wing and a target thrust.

In some examples, solving the system of relationships to determine the distribution of lift across the rotary wing further comprises: taking partial derivatives of the vortex circulation strengths across the sections of the rotary wing and a multiplier of the Lagrange method; and setting the partial derivatives to zero.

In some examples, the cost function includes a first tuning parameter applied to the torque and a second tuning parameter applied to a weighting function that penalizes wake characteristics produced along the rotary wing.

In some examples, the weighting function is based on an aggregated parameter, like the wing-hub bending moment, or is distributed in either uniform or log-based.

Some examples may include: determining a second plurality of chord lengths across the sections of the rotary wing of the rotorcraft; modifying the input parameters to incorporate the second plurality of chord lengths; iteratively repeating until the convergence criterion is met: (i) determining the inflow to the rotary wing, (ii) based on the input parameters as modified, redefining the system of relationships based on the vortex circulation strengths across the sections of the rotary wing, and (iii) solving the system of relationships to determine a second distribution of lift across the sections of the rotary wing; and based on the second distribution of lift and the second plurality of chord lengths, determining second local pitches for each of the sections of the rotary wing.

In some examples, determining the local pitch angles comprises, for each respective section of the rotary wing: determining an angle of attack for the respective section based on a lift coefficient, a zero-lift angle of attack, and a lift-curve slope; and determining a local pitch angle for the respective section based on adding the angle of attack to a velocity pitch angle that is produced by a combination of wake-induced and rotor freestream velocities.

### VII. Closing

The present disclosure is not to be limited in terms of the particular embodiments described in this application, which are intended as illustrations of various aspects. Many modifications and variations can be made without departing from its scope, as will be apparent to those skilled in the art. Functionally equivalent methods and apparatuses within the scope of the disclosure, in addition to those described herein, will be apparent to those skilled in the art from the foregoing descriptions. Such modifications and variations are intended to fall within the scope of the appended claims.

The above detailed description describes various features and operations of the disclosed systems, devices, and methods with reference to the accompanying figures. The example embodiments described herein and in the figures are not meant to be limiting. Other embodiments can be utilized, and other changes can be made, without departing from the scope of the subject matter presented herein. It will be readily understood that the aspects of the present disclosure, as generally described herein, and illustrated in the figures, can be arranged, substituted, combined, separated, and designed in a wide variety of different configurations.

With respect to any or all of the message flow diagrams, scenarios, and flow charts in the figures and as discussed herein, each step, block, and/or communication can represent a processing of information and/or a transmission of information in accordance with example embodiments. Alternative embodiments are included within the scope of these example embodiments. In these alternative embodiments, for example, operations described as steps, blocks, transmissions, communications, requests, responses, and/or messages can be executed out of order from that shown or discussed, including substantially concurrently or in reverse order, depending on the functionality involved. Further, more or fewer blocks and/or operations can be used with any of the message flow diagrams, scenarios, and flow charts discussed herein, and these message flow diagrams, scenarios, and flow charts can be combined with one another, in part or in whole.

A step or block that represents a processing of information can correspond to circuitry that can be configured to perform the specific logical functions of a herein-described method or technique. Alternatively or additionally, a step or block that represents a processing of information can correspond to a module, a segment, or a portion of program code (including related data). The program code can include one or more instructions executable by a processor for implementing specific logical operations or actions in the method or technique. The program code and/or related data can be stored on any type of computer readable medium such as a storage device including RAM, a disk drive, a solid-state drive, or another storage medium.

The computer readable medium can also include non-transitory computer readable media such as non-transitory computer readable media that store data for short periods of time like register memory and processor cache. The non-transitory computer readable media can further include non-transitory computer readable media that store program code and/or data for longer periods of time. Thus, the non-transitory computer readable media may include secondary or persistent long-term storage, like ROM, optical or magnetic disks, solid-state drives, or compact disc read only memory (CD-ROM), for example. The non-transitory computer readable media can also be any other volatile or non-volatile storage systems. A non-transitory computer readable medium can be considered a computer readable storage medium, for example, or a tangible storage device.

Moreover, a step or block that represents one or more information transmissions can correspond to information transmissions between software and/or hardware modules in the same physical device. However, other information transmissions can be between software modules and/or hardware modules in different physical devices.

The particular arrangements shown in the figures should not be viewed as limiting. It should be understood that other embodiments could include more or less of each element shown in a given figure. Further, some of the illustrated elements can be combined or omitted. Yet further, an example embodiment can include elements that are not illustrated in the figures.

While various aspects and embodiments have been disclosed herein, other aspects and embodiments will be apparent to those skilled in the art. The various aspects and embodiments disclosed herein are for purpose of illustration and are not intended to be limiting, with the true scope being indicated by the following claims.

What is claimed is:

1. A method comprising:
determining, by a computing system and for a rotorcraft, input parameters including a disk diameter, a rotary velocity, a thrust coefficient, and a plurality of chord lengths across sections of a rotary wing of the rotorcraft;
iteratively repeating, by the computing system, until a convergence criterion is met: (i) determining an inflow to the rotary wing, (ii) based on the input parameters, defining a system of relationships based on vortex circulation strengths across the sections of the rotary wing, and (iii) solving the system of relationships to determine a distribution of lift across the sections of the rotary wing; and
based on the distribution of lift and the plurality of chord lengths, determining, by the computing system, local pitch angles for each of the sections of the rotary wing.

2. The method of claim 1, further comprising:
manufacturing the rotary wing based on the chord lengths and local pitches for each of the sections of the rotary wing.

3. The method of claim 1, wherein the convergence criterion comprises the vortex circulation strengths remaining within a tolerance value between iterations.

4. The method of claim 1, wherein solving the system of relationships to determine the distribution of lift across the sections of the rotary wing comprises using a Lagrange method with a cost function that is based on torque produced by the rotary wing and a target thrust.

5. The method of claim 4, wherein solving the system of relationships to determine the distribution of lift across the rotary wing further comprises:
taking partial derivatives of the vortex circulation strengths across the sections of the rotary wing and a multiplier of the Lagrange method; and
setting the partial derivatives to zero.

6. The method of claim 4, wherein the cost function includes a first tuning parameter applied to the torque and a second tuning parameter applied to a weighting function that penalizes wake characteristics produced along the rotary wing.

7. The method of claim 6, wherein the weighting function is either uniform or log-based.

8. The method of claim 1, further comprising:
determining a second plurality of chord lengths across the sections of the rotary wing of the rotorcraft;
modifying the input parameters to incorporate the second plurality of chord lengths;
iteratively repeating until the convergence criterion is met: (i) determining the inflow to the rotary wing, (ii) based on the input parameters as modified, redefining the system of relationships based on the vortex circulation strengths across the sections of the rotary wing, and (iii) solving the system of relationships to determine a second distribution of lift across the sections of the rotary wing; and
based on the second distribution of lift and the second plurality of chord lengths, determining second local pitches for each of the sections of the rotary wing.

9. The method of claim 1, wherein determining the local pitch angles comprises, for each respective section of the rotary wing:
determining an angle of attack for the respective section based on a lift coefficient, a zero-lift angle of attack, and a lift-curve slope; and
determining a local pitch angle for the respective section based on adding the angle of attack to a velocity pitch angle that is produced by a combination of wake-induced and rotor freestream velocities.

10. A non-transitory computer-readable medium, having stored thereon program instructions that, upon execution by a computing system, cause the computing system to perform operations comprising:
determining, for a rotorcraft, input parameters including a disk diameter, a rotary velocity, a thrust coefficient, and a plurality of chord lengths across sections of a rotary wing of the rotorcraft;
iteratively repeating until a convergence criterion is met: (i) determining an inflow to the rotary wing, (ii) based on the input parameters, defining a system of relationships based on vortex circulation strengths across the sections of the rotary wing, and (iii) solving the system of relationships to determine a distribution of lift across the sections of the rotary wing; and
based on the distribution of lift and the plurality of chord lengths, determining local pitch angles for each of the sections of the rotary wing.

11. The non-transitory computer-readable medium of claim 10, the operations further comprising:
causing manufacture of the rotary wing based on the chord lengths and local pitches for each of the sections of the rotary wing.

12. The non-transitory computer-readable medium of claim 10, wherein the convergence criterion comprises the vortex circulation strengths remaining within a tolerance value between iterations.

13. The non-transitory computer-readable medium of claim 10, wherein solving the system of relationships to determine the distribution of lift across the sections of the rotary wing comprises using a Lagrange method with a cost function that is based on torque produced by the rotary wing and a target thrust.

14. The non-transitory computer-readable medium of claim 13, wherein solving the system of relationships to determine the distribution of lift across the sections of the rotary wing further comprises:
taking partial derivatives of the vortex circulation strengths across the sections of the rotary wing and a multiplier of the Lagrange method; and
setting the partial derivatives to zero.

15. The non-transitory computer-readable medium of claim 13, wherein the cost function includes a first tuning parameter applied to the torque and a second tuning parameter applied to a weighting function that penalizes wake characteristics produced along the rotary wing.

16. The non-transitory computer-readable medium of claim 15, wherein the weighting function is either uniform or log-based.

17. The non-transitory computer-readable medium of claim 10, the operations further comprising:
determining a second plurality of chord lengths across the sections of the rotary wing of the rotorcraft;
modifying the input parameters to incorporate the second plurality of chord lengths;
iteratively repeating until the convergence criterion is met: (i) determining the inflow to the rotary wing, (ii) based on the input parameters as modified, redefining the system of relationships based on the vortex circulation strengths across the sections of the rotary wing, and (iii) solving the system of relationships to determine a second distribution of lift across the sections of the rotary wing; and
based on the second distribution of lift and the second plurality of chord lengths, determining second local pitches for each of the sections of the rotary wing.

18. The non-transitory computer-readable medium of claim 10, wherein determining the local pitch angles comprises, for each respective section of the rotary wing:
determining an angle of attack for the respective section based on a lift coefficient, a zero-lift angle of attack, and a lift-curve slope; and
determining a local pitch angle for the respective section based on adding the angle of attack to a velocity pitch angle that is produced by a combination of wake-induced and rotor freestream velocities.

19. A system comprising:
one or more processors; and
memory, containing program instructions that, upon execution by the one or more processors, cause the system to perform operations comprising:
determining, for a rotorcraft, input parameters including a disk diameter, a rotary velocity, a thrust coefficient, and a plurality of chord lengths across sections of a rotary wing of the rotorcraft;
iteratively repeating until a convergence criterion is met: (i) determining an inflow to the rotary wing, (ii) based on the input parameters, defining a system of relationships based on vortex circulation strengths across the sections of the rotary wing, and (iii) solving the system of relationships to determine a distribution of lift across the sections of the rotary wing; and
based on the distribution of lift and the plurality of chord lengths, determining local pitch angles for each of the sections of the rotary wing.

20. The system of claim 19, wherein determining the local pitch angles comprises, for each respective section of the rotary wing:
determining an angle of attack for the respective section based on a lift coefficient, a zero-lift angle of attack, and a lift-curve slope; and
determining a local pitch angle for the respective section based on adding the angle of attack to a velocity pitch angle that is produced by a combination of wake-induced and rotor freestream velocities.
